(19) United States
(12) Patent Application Publication
(10) Pub. No.: US 2025/0336880 A1
(43) Pub. Date: Oct. 30, 2025

(54) WIREBONDING SYSTEMS AND RELATED METHODS

(71) Applicant: SEMICONDUCTOR COMPONENTS INDUSTRIES, LLC, Scottsdale, AZ (US)

(72) Inventors: Naima WANG, Suzhou (CN); Sen SUN, Suzhou (CN); Kun FENG, Shanghai (CN); LianYan WU, Suzhou (CN); ZhiNan LI, Kunshan (CN)

(73) Assignee: SEMICONDUCTOR COMPONENTS INDUSTRIES, LLC, Scottsdale, AZ (US)

(21) Appl. No.: 18/644,544

(22) Filed: Apr. 24, 2024

(51) Int. Cl. H01L 23/00

(52) U.S. Cl. CPC H01L 24/78; H01L 2224/78985; H01L 2224/78988; H01L 2924/40

(57) ABSTRACT

An anvil for a wirebonding system may include a stationary substrate having a top working surface; and a first layer fixedly coupled to the top working surface of the stationary substrate for receiving a workpiece, the first layer configured to accommodate a warped surface of the workpiece during a bonding operation.

### BACKGROUND

### 1. Technical Field

Aspects of this document relate generally to clamping systems. More specific implementations involve clamping systems for wirebonding tools.

### 2. Background

Semiconductor packages are utilized to protect semiconductor die and form interconnections between the semiconductor die and boards or systems designed to utilize the semiconductor die. The semiconductor die can be packaged using a wide variety of package designs including leadless packages and leaded packages. In some semiconductor package designs, the semiconductor die is coupled with a substrate or a leadframe.

### SUMMARY

An anvil for a wirebonding system may include a stationary substrate having a top working surface; and a first layer fixedly coupled to the top working surface of the stationary substrate for receiving a workpiece, the first layer configured to accommodate a warped surface of the workpiece during a bonding operation.

Implementations of an anvil for a wirebonding system may include one, all, or any of the following:
The first layer may include at least one of a soft material, a polymer, a polyimide, a silicone rubber, or a polyurethane rubber.
The first layer may be a coating applied to the top working surface of the stationary substrate.
The first layer may be elastic and yields to accommodate warpage of the workpiece.
The first layer may be removably attached to the stationary substrate or replaceable.
The first layer may be bonded, screwed, locked, or latched on the stationary substrate.

A clamping device for a wirebonding system may include an anvil and at least one clamping finger including at least one tip configured to clamp a substrate against the anvil during the bonding operation. A coating on a portion of the at least one tip may be included where the coated portion is configured to contact the substrate during the bonding operation.

A clamping device for a wirebonding system may include an anvil and at least one clamping finger including at least one tip configured to clamp a substrate against the anvil during the bonding operation where the at least one tip may include an insert on a distal end. The insert may include a soft material or polymer for contacting the substrate during the bonding operation.

Implementations of a clamp finger may include at least one tip configured to clamp a substrate against an anvil during a bonding operation and a coating on a portion of the at least one tip where the coated portion is configured to contact the substrate during the bonding operation.

Implementations of a clamp finger may include one, all, or any of the following:
The coating may be at least one of a soft material, a polymer, a polyimide, a silicone rubber, or a polyurethane rubber.
The coating may be dip coated.
The coating may be removable or replaceable.
The coating may form a cap covering a distal end of the at least one tip.

Implementations of a clamp finger may include at least one tip configured to clamp a substrate against an anvil during a bonding operation where the at least one tip may include an insert on a distal end where the insert includes a soft material or polymer for contacting the substrate during the bonding operation.

Implementations of a clamp finger may include one, all, or any of the following:
The soft material or polymer may be at least one of a polyimide, a silicone rubber, or a polyurethane rubber.
The insert may be removable or replaceable.
The soft material or polymer may extend across a width of the insert.
The soft material or polymer may extend across a width of the distal end of the at least one tip.
The insert may be an extension of the at least one tip and fixedly coupled to the distal end of the at least one tip.
The insert may be a male component and the at least one tip may be a female component

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a perspective view of an implementation of an anvil of a wirebonding system;

FIG. 2 is a perspective view of the wirebonding system and anvil of FIG. 1 including clamping fingers;

FIG. 3 is a top view of an implementation of a first layer of the anvil of FIG. 1;

FIG. 4 is a top view of an implementation of a trapezoidal first layer;

FIG. 5 is a top view of an implementation of a circular first layer;

FIG. 6 is a cross section view of an implementation of the first layer of FIG. 3;

FIG. 7 is a perspective view of an implementation of a clamping finger;

FIG. 8 is a perspective view of a distal end portion of the implementation of the clamping finger illustrated in FIG. 7;

FIG. 9 is a perspective view of a distal end portion of an implementation of a clamping finger having a T-shaped insert;

FIG. 10 is a perspective view of a distal end portion of an implementation of a clamping finger having a polygonal insert;

FIG. 11 is a perspective view of a distal end portion of an implementation of a clamping finger having a stepped insert; and

FIG. 12 is a perspective view of a distal end portion of an implementation of a dip coated clamping finger.

### DESCRIPTION

This disclosure, its aspects and implementations, are not limited to the specific components, assembly procedures or method elements disclosed herein. Many additional components, assembly procedures and/or method elements known in the art consistent with the intended wirebonding and clamping systems and devices will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such wirebonding and clamping systems and devices, and implementing components and methods, consistent with the intended operation and methods.

During fabrication, wire bonding is the process of bonding bond wires to workpieces to connect the workpieces to packaging substrates or other components. The workpieces may be semiconductor devices, direct bonded copper substrates, circuit boards, or leadframes, Wire bonding machines need to be able to accurately place each bond wire on the workpieces and packaging substrates during the wirebonding operation. When the wire bonds are not properly formed, the workpieces will not function properly. In practice, the wire bonds can be improperly formed or damaged after formation by lifting off the semiconductor devices, suffering physical damage or cracking. Slight variations/changes in the orientation of the workpiece with respect to the wire bonding equipment during or after the wirebonding operation may be sufficient to cause damage the wire bonds.

Workpieces may be warped, uneven, buckled or deformed as a result of upstream processing operations. When these warped, uneven, buckled or deformed workpieces are deposited directly on flat anvils, the workpieces do not lay flat on the flat top surfaces of the anvils owing to their warped uneven, buckled or deformed surfaces. As a result, the wirebonding systems may have difficulty securing the workpieces in place during the wirebonding operations because the clamping fingers and anvils are not able to provide the desired hold or grip on the workpieces. The unbalanced clamping and poor hold performance may result in undesired defects during the wirebonding process including bond lift, bond damage, bond cracking and other defects or even cracking of the substrate caused by too much localized pressure on a warped or otherwise deformed portion of the substrate.

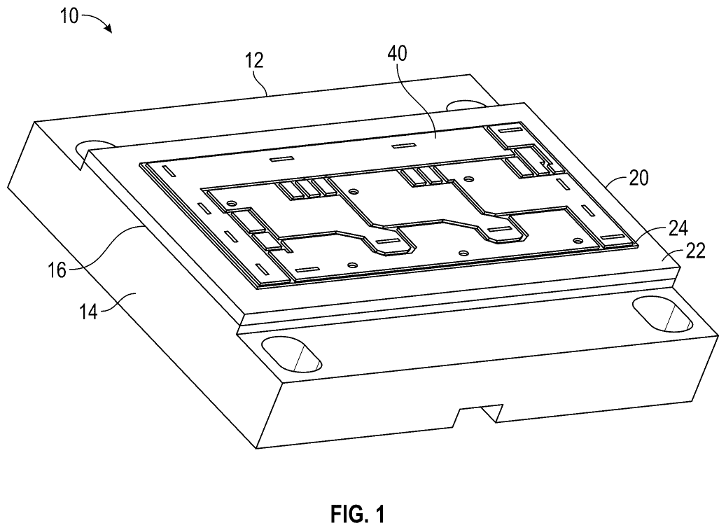

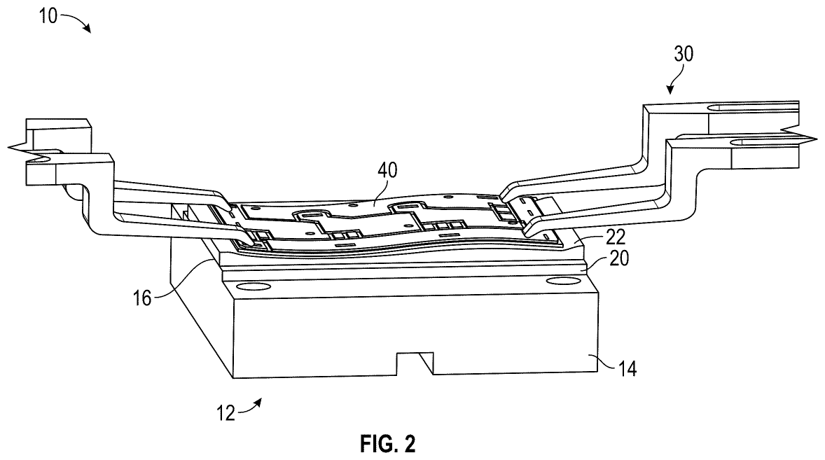

Example of clamp/clamping fingers with various mechanically adjustable designs to accommodate variations in substrates may be found in U.S. Pat. App. Pub. No. 20240051089 to Sun et al., entitled “Adjustable clamp finger design,” filed Aug. 12, 2022 and published Feb. 15, 2024, the disclosure of which is hereby incorporated entirely herein by reference. Referring now to FIGS. 1 and 2, an implementation of a wirebonding system 10 is illustrated. The wirebonding system 10 includes an anvil 12 and a plurality of clamping fingers 30. The anvil 12 and clamping fingers 30 are used together in various implementations of wirebonding tools to support a workpiece 40 in a fixed position vertically and horizontally while one or more bond heads operating using bond wires in the form of capillaries or wedges to form wirebonds between one or more pads on one or more substrates and the workpiece. A wide variety of wirebond types and wirebond metal types may be used in combination with anvil 12 and clamping fingers 30 implementations disclosed herein.

Referring to FIG. 1, anvil 12 includes a base or stationary substrate 14 having a top working surface 16. In some implementations the base or stationary substrate 14 is made of steel, iron or another hard material. In some implementations the workpiece 40 is a semiconductor device, a leadframe or a direct bonded copper substrate.

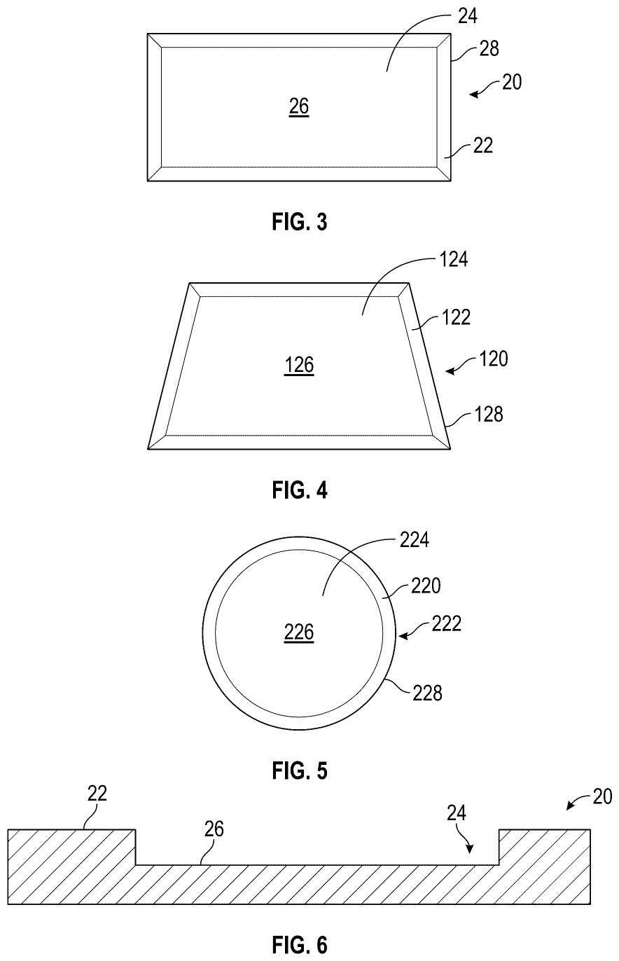

Wirebonding system 10 also includes a first layer 20 on top working surface 16 of anvil 12 for supporting workpiece 40. First layer 20 is fixedly coupled to top working surface 16 of anvil 12. First layer 20 includes a top surface 22 having a recess 24 that accommodates workpiece 40. The workpiece 40 rests on a recessed surface 26 illustrated in FIGS. 3 and 6. First layer 20 is made of at least one soft material. In some implementations, the soft material is one of a polymer, a polyimide, a silicone rubber, or a polyurethane rubber. In some implementations, the first layer has elastic properties, i.e., the first layer is able to deform under force and regain shape when the force is removed. In some implementations, the top surface 22 does not include a recess and the workpiece is received directly onto top surface 22.

As illustrated in FIG. 2, first layer 20 accommodates a workpiece 40 having a warped, uneven, buckled or deformed surface during a bonding operation because the material of first layer 20 is able to yield or otherwise change shape to correspond with the surface of the workpiece. For example, first layer 20 may warps in the same manner workpiece 40 is warped. First layer 20 can yield or change shape to fit workpiece 40 as needed to provide more surface area contact to a bottom warped surface of workpiece 40 than the hard and flat top working surface 16 of anvil 12 would be able to provide. Consequently, workpiece 40 is better supported by first layer 20 than workpiece 40 would be supported by anvil 12 alone. By including first layer 20 on anvil 12, wirebonding system 10 can improve the hold performance of workpiece 40 during bonding operations which results in improved bond performance. The first layer 20 can also work to prevent damage to the substrate and/or the wirebonds after formation due to excessive local pressures being applied to the substrate or movement of the substrate surfaces after wirebonded that could crack the wirebonds formed.

In some implementations, the first layer is removably attached to the stationary substrate and is replaceable if wear is noted upon a visual inspection of the first layer during operation. In various implementations, the first layer is bonded, screwed, locked, or latched on the stationary substrate. Where the first layer 20 is bonded, the bonding may take place using a glue, adhesive, or other chemical bond to the top working surface 16 of the anvil 12. In further implementations, the first layer is a coating applied to/formed on the top working surface 16 of the anvil 12. Where the first layer is a coating, it may be applied/formed on the top working surface 16 in several ways, including, by non-limiting example, dipping, painting, spraying stenciling, depositing, or any other method consistent with applying/forming a coating of the particular material used for the first layer. Non-limiting examples of materials that may be used for the first layer 20 include rubbers, silicones, polymers, epoxies, or other materials capable of reversibly deformably yielding under applied pressure.

FIG. 3 illustrates a top view of first layer 20 of anvil 12 illustrated in FIG. 1. As described above, first layer 20 includes a top surface 22, a recess 24 and a recessed surface 26 (recessed into the paper) configured to accommodate a shape of a perimeter of a workpiece. Recessed surface 26 receives the workpiece thereon. The dimensions and geometry of first layer 20 are sized to accommodate both particularly sized workpieces and particularly sized anvils used during the wirebonding operation. The particular size of the first layer can depend on the workpiece size, the anvil size, or both in various system implementations. As illustrated from the top view of FIG. 3, a perimeter 28 of first layer 20 may be rectangular. In some implementations, the perimeter may be square.

FIG. 4 is a top view of an implementation of a first layer 120 with a trapezoidal perimeter. First layer 120 includes a top surface 122 and a recess 124 configured to accommodate a workpiece. The workpiece may or may not be trapezoidal itself, as the trapezoidal shape may be driven by the shape of the particular anvil being used. Recessed surface 126 receives a workpiece thereon. The dimensions and geometry of first layer 120 are sized to accommodate workpieces, anvils or both workpieces and anvils used during the wirebonding operation. As illustrated from the top view of FIG. 4, a perimeter 128 of first layer 120 forms an isosceles trapezoid though other trapezoidal shapes, such as right, acute, obtuse, rhomboid, or parallelogram shapes may be utilized in other implementations. In some implementations, the perimeter may be a polygon or any another closed shape.

FIG. 5 is a top view of an implementation of a first layer 220 with an elliptically shaped first layer. First layer 220 includes a top surface 222 and a recess 224 configured to accommodate a workpiece. Recessed surface 226 receives a workpiece thereon/therein. The dimensions and geometry of first layer 220 are sized to accommodate workpieces, anvils, or workpieces and anvils used during the wirebonding operation. As illustrated from the top view of FIG. 5, a perimeter 228 of first layer 220 is a circle. In some implementations, the perimeter may be any other type of ellipsis.

FIG. 6 is a cross sectional view of the implementation of the first layer of FIG. 3. FIG. 6 illustrates the relationship of the first layer 20, top surface 22, recess 24, and howe the recessed surface 26 allows the workpiece to physically rest in the recess. During a wirebonding operation, the thickness of a workpiece is placed into recessed surface 26 at least partially so the workpiece rests at least partially within recess 24.

In some implementations, as illustrated from the from the top views of FIGS. 3-5, the shape of the perimeter of the first layer may be different from the shape of the perimeter of a recess. For example, a perimeter of the first layer may be elliptical while a perimeter of the recess is rectangular. A wide variety of combinations of perimeter shapes and recess perimeter shapes along with cross-sectional shapes (square, slanting, curved, etc.) for the first layer may be employed in various implementations.

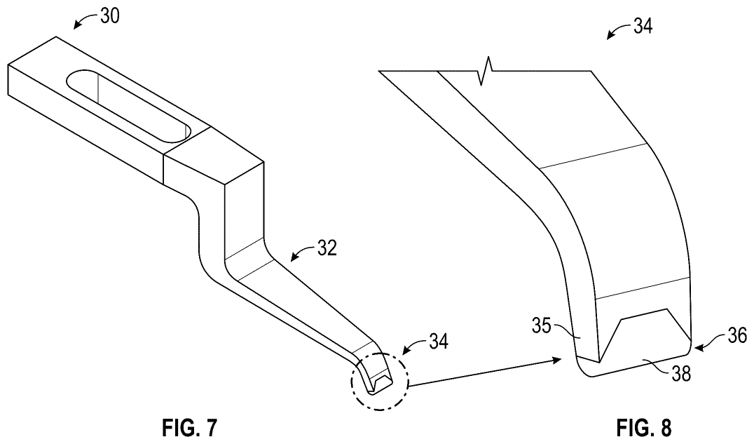

The various first layer implementations disclosed herein may be utilized in conjunction with various clamp/clamping finger implementations. With respect to clamping fingers, FIG. 7 illustrates a perspective view of an implementation of a clamping finger 30. Clamping finger 30 is used in implementations of wirebonding tools to hold a workpiece in a fixed position vertically and horizontally against an anvil during a bonding operation (see FIG. 2). One end of clamping finger 30 is fixedly held in place using a screw or bolt while the tip portion of the clamping finger contacts the workpiece at a desired location. As illustrated in FIG. 7, clamping finger 30 includes a tip portion 32 having a distal end portion 34. The distal end portion 34 contacts and holds the workpiece in place against an anvil (or first layer, where a first layer is employed with the anvil).

FIG. 8 is a perspective detail view of the distal end portion 34 of the implementation of the clamping finger 30 illustrated in FIG. 7. Distal end portion 34 includes a contact area 36 on the end thereof having an insert 38 that is used to directly contact a workpiece on an anvil. In some implementations, a width of insert 38 extends across a width of contact area 36 which directly contacts the workpiece. Insert 38 is made of a soft material or polymer which improves hold performance of clamping finger 30 because insert 38 provides a better material and texture for gripping in the contact area than the metal tips of other clamping fingers. The soft material or polymer of insert 38 can absorb some of the pressure from the workpiece due to warping or other deformation which reduces wiggling and the localized pressure applied to the workpiece the clamping finger. By providing flexibility and give during setup and processing, the insert can consistently contact the workpiece during wirebonding. Thus, the use of the insert 38 in the distal end portion 34 improves the hold on the workpiece which can result in improved wirebond performance.

In some implementations, the soft material or polymer used is, by non-limiting example, a polyimide, a silicone rubber, or a polyurethane rubber. In various implementations, the soft material or polymer extends across the entire a width of the insert. In further implementations, the soft material or polymer extends partially across the width of the insert.

In some implementations, insert 38 is removable and replaceable when wear is noted on the material of the insert 38. Insert 38 may be coupled to distal end portion 34 in numerous ways. As illustrated in FIG. 8, insert 38 fits snugly into a frame 35 of distal end portion 34 of clamping finger 30. Frame 35 serves as a female receptor and insert 38 serves as a male component. In some implementations, the insert is an extension of the clamping finger and fixedly coupled to the distal end portion through a fastener, set screw, screw, pin, or other locking mechanism. In various implementations, the insert includes one piece whereas in other implementations the insert may be made of a plurality of separate components that are bonded, welded, glued, or otherwise fixedly coupled together.

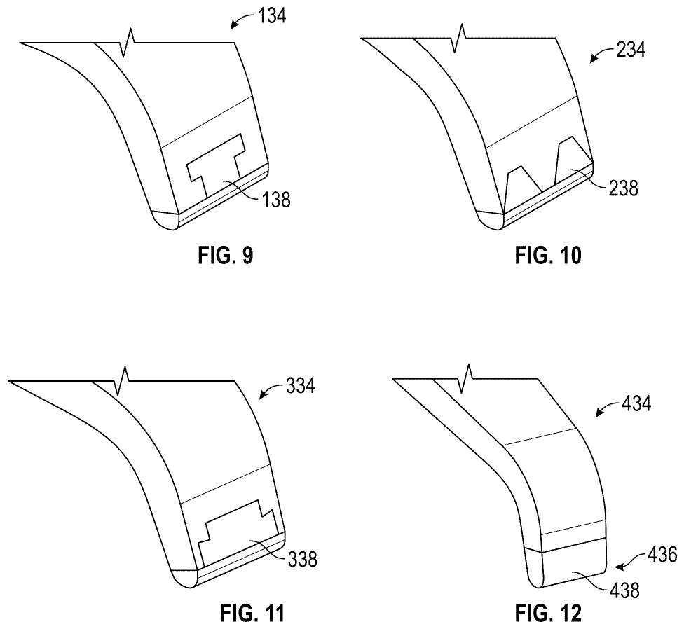

Referring to FIG. 9, a perspective view of a distal end portion of an implementation of a clamping finger having a T-shaped insert 138 is illustrated. Distal end portion 134 includes an insert 138 on an end thereof that contacts the workpiece on the anvil (or on the first layer, depending on the implementation). As illustrated, insert 138 extends across a width of the distal end portion 134. A top portion of insert 138 has a T-shaped appearance when viewed from the front. Insert 138 is made of a soft material or polymer like any disclosed herein which can improve the hold performance of the clamping finger for the reasons discussed above with respect to FIGS. 7 and 8.

FIG. 10 is a perspective view of a distal end portion of an implementation of a clamping finger having an insert composed of polygonal shapes. As illustrated, distal end portion 234 includes an insert 238 on an end thereof for contacting a workpiece on an anvil that extends across a width of the distal end portion 234. A top portion of insert 238 has a polygonal appearance when viewed from the front and is constructed of two trapezoidal shapes connected together. Insert 238 is made of any of the soft material or polymer materials disclosed herein to improve hold performance of the clamping finger for the reasons discussed above with respect to FIGS. 7 and 8.

Referring to FIG. 11, a perspective view of a distal end portion of an implementation of a clamping finger having a stepped-shaped insert is illustrated. Distal end portion 334 portion includes the stepped insert 338 on an end thereof for contacting a workpiece on an anvil (or first layer, depending on the implementation). As illustrated, insert 338 extends across the width of the distal end portion 334 of the clamping finger. A top portion of insert 338 has a stepped appearance when viewed from the front with the upper portion being narrower than the lower portion. However, in other implementations, this shape could be reversed where the upper portion is wider than the lower portion. Insert 338 is made of a soft material or polymer like any disclosed herein which may improve the hold performance of the clamping finger for the reasons discussed above with respect to FIGS. 7 and 8.

FIG. 12 is a perspective view of a distal end portion of another implementation of a coated clamping finger. In this implementation, a distal end portion 434 of a clamping finger includes a coated tip 438 which is used to contact the workpiece. The coated tip 438 is a coating made of a soft material or polymer like any coating material disclosed herein which works to improve the hold performance of the clamping finger for the reasons discussed above with respect to FIGS. 7 and 8. As illustrated in FIG. 12, the coating extends across a width of the distal end portion 434. In some implementations, the coated tip is dip coated or coated using any other coating technique disclosed herein. In various implementations, the coating may be removable or replaceable or extend only partially across a width of the distal end. In further implementations, the coating may be designed as a cap or sock that can be placed on the distal end portion of a clamping finger.

During repeated wirebonding operation, it has been observed that the metal of the ends of the tips of the clamping fingers in the contact area wears under the pressure and movement of the workpiece against the tips during processing of multiple workpieces through the wirebonding tool. Thus, at some point during operation, given enough wear, a given clamping finger may no longer be able to securely hold the workpiece in position and the clamping finger then has to be entirely discarded as unsuitable for future use. The use of replaceable inserts and/or the coatings may allow the inserts and/or coatings to be replaced or reapplied so the clamping fingers when wear is noted so the clamping fingers may be used again subsequently reducing waste and costs associated with discarding worn clamping fingers.

Referring back to FIG. 2, the wirebonding system 10 may include any clamping finger implementation described herein in any combination. Accordingly, one or more clamping fingers 30 may have an insert including a soft material or polymer for contacting a workpiece as described with reference to FIGS. 7 to 11. One or more clamping fingers 30 may have a coated tip as described with reference to FIG. 12. Wirebonding system 10 may include any combination of clamping fingers implementations 30 described herein, and in some implementations, may be mixed with one or more clamping fingers that have only metal tips depending upon the requirements for a particular workpiece.

Implementation of the anvils disclosed herein and implementations of the clamping fingers disclosed herein may be easy to upgrade or retrofit with existing anvil and wirebonding tool designs with low costs. Furthermore, as disclosed herein, the combination of the soft first layer and the clamping finger implementations disclosed herein may help ensure accurate processing of the workpieces while minimizing the risk of damage.

The wirebonding systems disclosed herein and various implementations thereof may also reduce bond yield loss caused by bond lift, bond damage and bond cracking t.

In places where the description above refers to particular implementations of the wirebonding and clamping systems and devices, and implementing components, sub-components, methods and sub-methods, it should be readily apparent that a number of modifications may be made without departing from the spirit thereof and that these implementations, implementing components, sub-components, methods and sub-methods may be applied to other wirebonding and clamping systems and devices.

What is claimed is:

1. An anvil for a wirebonding system comprising:
a stationary substrate having a top working surface; and
a first layer fixedly coupled to the top working surface of the stationary substrate for receiving a workpiece, the first layer configured to accommodate a warped surface of the workpiece during a bonding operation.

2. The anvil of claim 1, wherein the first layer comprises at least one of a soft material, a polymer, a polyimide, a silicone rubber, or a polyurethane rubber.

3. The anvil of claim 1, wherein the first layer is a coating applied to the top working surface of the stationary substrate.

4. The anvil of claim 1, wherein the first layer is elastic and yields to accommodate warpage of the workpiece.

5. The anvil of claim 1, wherein the first layer is removably attached to the stationary substrate or replaceable.

6. The anvil of claim 5, wherein the first layer is bonded, screwed, locked, or latched on the stationary substrate.

7. A clamping device for a wirebonding system comprising:
the anvil of claim 1; and
at least one clamping finger comprising:
at least one tip configured to clamp a substrate against the anvil during the bonding operation; and
a coating on a portion of the at least one tip, the coated portion configured to contact the substrate during the bonding operation.

8. A clamping device for a wirebonding system comprising:
the anvil of claim 1; and
at least one clamping finger comprising:
at least one tip configured to clamp a substrate against the anvil during the bonding operation;
wherein the at least one tip comprises an insert on a distal end;
wherein the insert comprises a soft material or polymer for contacting the substrate during the bonding operation.

9. A clamp finger comprising:
at least one tip configured to clamp a substrate against an anvil during a bonding operation; and
a coating on a portion of the at least one tip, the coated portion configured to contact the substrate during the bonding operation.

10. The clamp finger of claim 9, wherein the coating is at least one of a soft material, a polymer, a polyimide, a silicone rubber, or a polyurethane rubber.

11. The clamp finger of claim 9, wherein the coating is dip coated.

12. The clamp finger of claim 9, wherein the coating is removable or replaceable.

13. The clamp finger of claim 9, wherein the coating forms a cap covering a distal end of the at least one tip.

14. A clamp finger comprising:
at least one tip configured to clamp a substrate against an anvil during a bonding operation;
wherein the at least one tip comprises an insert on a distal end;
wherein the insert comprises a soft material or polymer for contacting the substrate during the bonding operation.

15. The clamp finger of claim 14, wherein the soft material or polymer is at least one of a polyimide, a silicone rubber, or a polyurethane rubber.

16. The clamp finger of claim 14, wherein the insert is removable or replaceable.

17. The clamp finger of claim 14, wherein the soft material or polymer extends across a width of the insert.

18. The clamp finger of claim 14, wherein the soft material or polymer extends across a width of the distal end of the at least one tip.

19. The clamp finger of claim 14, wherein the insert is an extension of the at least one tip and fixedly coupled to the distal end of the at least one tip.

20. The clamp finger of claim 14, wherein the insert is a male component and the at least one tip is a female component.
